(19) United States
(12) Patent Application Publication
(10) Pub. No.: US 2026/0063706 A1
(43) Pub. Date: Mar. 5, 2026

(54) BIAS TEMPERATURE INSTABILITY (BTI) MEASUREMENT SYSTEM

(71) Applicant: TEXAS INSTRUMENTS INCORPORATED, DALLAS, TX (US)

(72) Inventors: VIJAY KUMAR REDDY, Plano, TX (US); ARIF SONNET, Richardson, TX (US); DHANOOP VARGHESE, Plano, TX (US); SRIKANTH KRISHNAN, Plano, TX (US); VIJAYA VEMURI, Dallas, TX (US)

(21) Appl. No.: 18/820,931

(22) Filed: Aug. 30, 2024

(51) Int. Cl. G01R 31/28; H01L 27/06

(52) U.S. Cl. CPC G01R 31/287; H10D 84/811

(57) ABSTRACT

One example includes a method for performing a BTI test process of DUTs. The method includes coupling contact pads of a DUT circuit to testing equipment. The DUT circuit includes a differential input stage and a gain stage. The differential input stage include a differential pair of transistors that are fabrication matched to the DUTs. The method also includes providing a BTI stress from the testing equipment to one of the differential pair of transistor devices to simulate BTI aging of the respective one of the differential pair of the transistors. The method also includes providing a differential input voltage from the testing equipment to the differential input stage. The method further includes measuring an output voltage at an output of the gain stage via the testing equipment in response to the differential input voltage to determine a threshold voltage change between the differential pair of transistor devices.

### TECHNICAL FIELD

This description relates to testing of electronic circuits, and more specifically to a BTI measurement system.

### BACKGROUND

Semiconductor devices (e.g., integrated circuits (ICs)) can experience parametric shifts over the operational lifetime of the respective devices. Fabricators of such devices typically want to predict such parametric shifts as a measure of reliability of the devices, such that the device parametric limits can be specified to detect potential failures caused by deviation from the parametric limits. For high precision devices, such as high precision operational amplifiers (OP-AMPs), parametric shifts can include offset voltage shifts, and can be very low in value (e.g., in the microvolt range). One way to predict parametric shifts, particularly for transistor devices, is by implementing bias temperature instability (BTI) testing. The BTI testing can be implemented for semiconductor devices fabricated in bulk on a semiconductor wafer.

During a testing phase, the fabricated ICs can undergo a variety of different operational tests using testing equipment, such as BTI testing.

### SUMMARY

One example includes a method for performing a bias temperature instability (BTI) test process of devices-under-test (DUTs). The method includes coupling contact pads of a DUT circuit to testing equipment. The DUT circuit includes a differential input stage and a gain stage. The differential input stage include a differential pair of transistor devices that are fabrication matched to the DUTs. The method also includes providing a BTI stress from the testing equipment to one of the differential pair of transistor devices to simulate BTI aging of the respective one of the differential pair of transistor devices. The method also includes providing a differential input voltage from the testing equipment to the differential input stage. The method further includes measuring an output voltage at an output of the gain stage via the testing equipment in response to the differential input voltage to determine a threshold voltage change between the differential pair of transistor devices.

Another example includes a circuit. The circuit includes a current source stage having a first input, a second input, and a first output and a second output. The first input of the current source stage can be adapted to receive a bias voltage, and the second input of the current source stage can be adapted to receive a bias control voltage. The circuit also includes a differential input stage comprising a first input transistor device and a second input transistor device. The first input transistor device can have a control input, an input, an output, and a terminal. The second input transistor device can have a control input, an input, an output, and a terminal. The control input of the first input transistor device can be adapted to receive a first control input voltage, the control input of the second input transistor device can be adapted to receive a second control input voltage, the input of each of the first and second input transistor devices can be coupled to the first output of the current source stage, and the terminal of the first input transistor device can be coupled to the terminal of the second input transistor device. The circuit also includes a current mirror stage having a first input, a second input, and an output. The first input of the current mirror stage can be coupled to the output of the first input transistor device, and the second input of the current mirror stage can be coupled to the output of the second input transistor device. The circuit also includes a gain stage having a first input, a second input, and an output. The first input of the gain stage can be coupled to the output of the second input transistor device, the second input of the gain stage can be coupled to the second output of the current source stage, and the output of the gain stage can be coupled to the output of the current mirror stage. The circuit also includes a first contact pad coupled to the control input of the first input transistor device, a second contact pad coupled to the control input of the second input transistor device, a third contact pad coupled to the second input of each of the first and second input transistor devices, a fourth contact pad coupled to the output of the first input transistor device, a fifth contact pad coupled to the output of the second input transistor device, a sixth contact pad coupled to the terminal of the first and second input transistor devices, and a seventh contact pad coupled to the second input of the gain stage.

Another example includes a test system for performing a BTI test process of a plurality of DUTs. The system includes a semiconductor wafer. The semiconductor wafer includes the plurality of circuit dies. Each of the circuit dies includes at least one DUT. The semiconductor wafer also includes at least one DUT circuit each comprising a differential input stage and a gain stage. The differential input stage includes a differential pair of transistor devices that are fabrication matched to the DUTs. The system further includes testing equipment to which contact pads of the DUT circuit are arranged to be coupled. The testing equipment can be configured to provide BTI stress to one of the differential pair of transistor devices to simulate BTI aging of the respective one of the differential pair of transistor devices, to provide a differential input voltage to the differential pair of transistor devices, and to measure an output voltage at an output of the gain stage in response to the differential input voltage to determine a threshold voltage change between the differential pair of transistor devices.

Another example includes a semiconductor wafer. The wafer includes a plurality of circuit dies. Each of the circuit dies comprising at least one DUT. The wafer also includes a plurality of DUT circuits. Each of the DUT circuits includes a current source stage configured to provide a first current and a second current. Each of the DUT circuits also includes a differential input stage comprising a differential pair of transistor devices that are each configured to conduct a portion of the first current in response to receiving a respective differential input voltage. Each of the differential pair of transistor devices can be fabrication matched to the at least one DUT of each of the circuit dies. Each of the DUT circuits also includes a current mirror stage coupled to the differential input stage. The current mirror stage includes a bias terminal through which the portion of the first current is provided. Each of the DUT circuits also includes a gain stage coupled to the bias terminal and being configured to provide an output voltage based on the second current in response to the differential input voltage. Each of the DUT circuits further includes contact pads configured to provide a BTI stress to one of the differential pair of transistor devices to perform a BTI test of the at least one DUT of each of the circuit dies via the respective one of the DUT circuits.

### BRIEF DESCRIPTION OF THE DRAWINGS

FIG. 1 is an example block diagram of a circuit test system.

FIG. 2 is an example diagram of a semiconductor wafer.

FIG. 3 is an example block diagram of a device under test (DUT) circuit.

FIG. 4 is an example diagram of a DUT circuit.

FIG. 5 is an example of a voltage graph.

FIG. 6 is an example of a method for testing a DUT.

### DETAILED DESCRIPTION

This description relates to testing of electronic circuits, and more specifically to a bias temperature instability (BTI) measurement system. A circuit test system can implement testing one or more devices-under-test (DUTs) in a testing phase of fabrication of semiconductor circuit devices, such as at a semiconductor wafer level. Testing equipment can be electrically coupled to contact pads of a DUT circuit that is fabricated on the wafer. As described in greater detail herein, the testing equipment can provide a BTI test of transistor devices of the DUT circuit that are fabrication matched to the DUTs. As described herein, the term “fabrication matched” describes a relationship between two semiconductor devices (e.g., transistor devices) that are fabricated approximately identically or proportionally, such that fabrication process tolerances and temperature effects can affect the two semiconductor devices in approximately the same manner. The testing equipment can thus conduct the BTI test of the transistor device of the DUT circuit to simulate the effects of aging on the DUT(s) on the semiconductor wafer.

The DUT circuit can include a differential input stage that includes a differential transistor pair, with each of the transistor devices of the differential transistor pair being fabrication matched to each other and to the DUTs on the semiconductor wafer. The DUT circuit can also include a gain stage that is configured to provide an output voltage in response to a differential input voltage provided to the differential input stage, and thus to the differential pair of transistor devices. To conduct the BTI test, the testing equipment can electrically couple to the contact pads of the DUT circuit to measure the output voltage in response to providing the differential input voltage. As an example, the testing equipment can provide a continuously variable amplitude of one input voltage of the differential input voltage relative to a fixed amplitude of the other input voltage of the differential input voltage, and can measure the resultant continuously changing output voltage. The testing equipment can thus obtain a baseline measurement of the output voltage.

After obtaining the baseline measurement of the output voltage, the testing equipment can provide a BTI stress to one of the transistor devices of the differential transistor pair. As described herein, the term “BTI stress” refers to a manner of simulating aging of the transistor device. The BTI stress can be provided in a variety of ways to simulate the aging, such as by providing a predefined voltage to a control input (e.g., gate) of the transistor device while grounding all other terminals of the transistor device (e.g., including a substrate body connection) at a predefined temperature. As an example, such a BTI stress can result in breakdown of silicon-hydrogen bonds at the poly-silicon gate resulting from an accumulation of electrons tunneling from the substrate of the transistor device to introduce defects in the transistor device. For example, the BTI stress on a transistor device can result in an increase in a threshold voltage V_{T} and a decrease in a saturation current I_{DSAT}, which can be provided as characteristic information of predicted parametric shifts of the DUTs on the wafer.

To complete the BTI test, the testing equipment can again measure the output voltage in response to providing the differential input voltage. As an example, after obtaining the continuously variable output voltage during the baseline measurement, the testing equipment can measure the output voltage at a specific amplitude of the differential input voltage. Thus, after providing the BTI stress, the testing equipment can measure the output voltage at the same specific amplitude of the differential input voltage to determine a difference in the threshold voltage of the differential transistor pair resulting from the BTI stress.

For example, the testing equipment can measure a gain of the DUT circuit based on a slope of the continuously variable output voltage (e.g., during the baseline determination). The testing equipment can thus divide the difference in output voltage by the gain of the DUT circuit to determine the change in threshold voltage of the BTI stressed transistor device. Because of the gain of the DUT circuit, the change in threshold voltage can be measured in the microvolt range, as opposed to conventional parametric shift modeling techniques that can achieve only a millivolt range of precision. Accordingly, the change in threshold voltage of the BTI stressed transistor device can correspond to the predicted parametric shifts of the DUTs on the wafer.

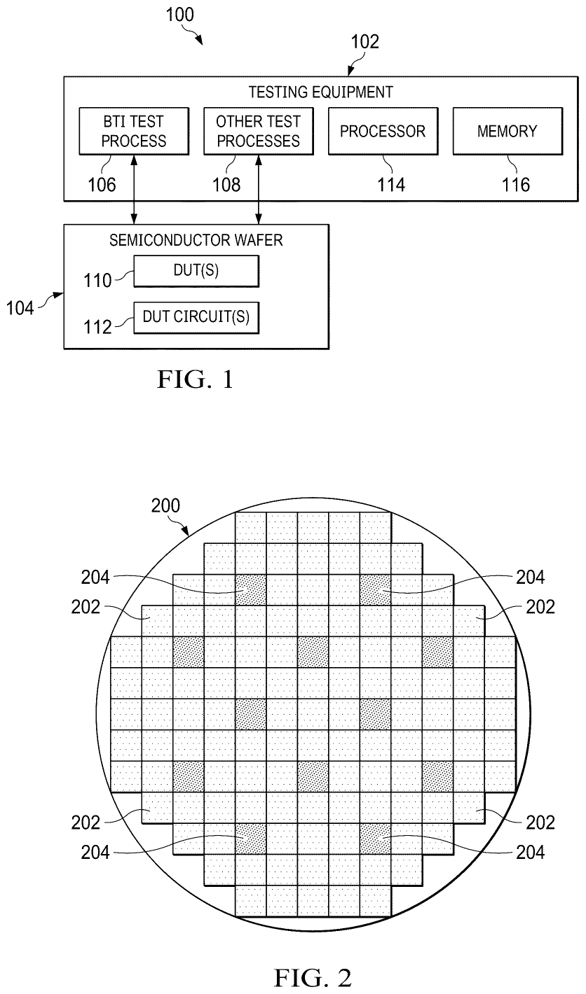

FIG. 1 is an example block diagram of a circuit test system 100. The circuit test system 100 can be implemented to provide bias temperature instability (BTI) testing of one or more devices-under-test (DUTs), as described herein. The circuit test system 100 includes testing equipment 102 that can correspond to any of a variety of circuit test equipment (e.g., automated testing equipment (ATE)). The testing equipment 102 is configured to perform a variety of tests on a semiconductor wafer 104 after fabrication of the semiconductor wafer 104. In the example of FIG. 1, the testing equipment 102 is configured to perform a BTI test process 106 and other test processes 108. The other test processes 108 can include any of a variety of standard tests on fabricated semiconductor devices, such as parametric tests and current tests.

In the example of FIG. 1, the semiconductor wafer 104 includes a plurality of DUTs 110 and at least one DUT circuit 112. As described herein, the testing equipment 102 is configured to implement the BTI test process 106 on the DUT circuit(s) 112 to provide parametric shift data for the DUTs 110 based on measured results of the BTI test process 106 on the DUT circuit(s) 112. The testing equipment 102 includes a processor 114 that includes instructions as to the manner of performing the BTI test process 106, as well as the other test processes 108, and a memory 116 for recording the results of the BTI and other test processes 106 and 108. Accordingly, the parametric shift data for the DUTs 110 can be stored in and accessed from the memory 116.

Each of the DUT circuit(s) 112 can include a differential input stage that includes a differential transistor pair. Each of the transistor devices of the differential transistor pair can be fabrication matched to each other and to the DUTs 110 on the semiconductor wafer 104. Each of the DUT circuit(s) 112 can also include a gain stage that is configured to provide an output voltage in response to a differential input voltage provided to the differential input stage, and thus to the differential pair of transistor devices. To conduct the BTI testing process, the testing equipment can electrically couple to contact pads of the DUT circuit(s) 112 to measure the output voltage in response to providing the differential input voltage. As an example, the DUT circuit(s) 112 can include contact pads at each node to facilitate a BTI stress of one of the transistor devices of the differential input stage to facilitate the BTI testing process 106.

As described in greater detail herein, the BTI testing process 106 of a given DUT circuit 112 can include a measurement of the output voltage both before and after a BTI stress provided during the BTI testing process 106. As an example, the testing equipment 102 can obtain a continuously variable output voltage during a baseline measurement, from which the testing equipment 102 can determine a gain of the respective DUT circuit 112 and can measure the output voltage at a specific amplitude of the differential input voltage. Thus, after providing the BTI stress, the testing equipment can measure the output voltage at the same specific amplitude of the differential input voltage to determine a difference in the threshold voltage of the differential transistor pair resulting from the BTI stress. Because of the high gain of the DUT circuit 112, as measured by the testing equipment 102, the change in threshold voltage can be measured in the microvolt range, as opposed to conventional parametric shift modeling techniques that can achieve only a millivolt range of precision. Accordingly, the change in threshold voltage of the BTI stressed transistor device can correspond to a predicted parametric shifts of each of the DUTs 110 on the semiconductor wafer 104 based on the fabrication matching of the transistor devices of the DUT circuit(s) 112 to the DUTs 110 on the semiconductor wafer 104.

FIG. 2 is an example diagram of a semiconductor wafer 200. The semiconductor wafer 200 can correspond to the semiconductor wafer 104 in the example of FIG. 1. Therefore, reference is to be made to the example of FIG. 1 in the following example of FIG. 2.

In the example of FIG. 2, the semiconductor wafer 200 is demonstrated as a circular disk, though the semiconductor wafer 200 can have any of a variety of shapes. The semiconductor wafer 200 includes a plurality of circuit dies 202 distributed across a top surface. Each of the circuit dies 202 can include at least one DUT, such as the DUTs 110 in the example of FIG. 1. The semiconductor wafer 200 also includes a plurality of DUT circuits 204, such as the DUT circuit(s) 112 in the example of FIG. 1, that are likewise distributed across the top surface of the semiconductor wafer 200. In the example of FIG. 2, the DUT circuits 204 can be distributed about the surface of the semiconductor wafer 200, such as evenly in an array and/or approximately equidistant from each other. Additionally, the quantity and distribution of the circuit dies 202 and the DUT circuits 204 is demonstrated by example, such that the circuit dies 202 and the DUT circuits 204 can be arranged in any of a variety of ways, and can number significantly greater than demonstrated in the example of FIG. 2.

As described above, the DUT circuits 204 can include a differential pair of transistor devices that are fabrication matched to the DUT(s) of each of the circuit dies 202 on the semiconductor wafer 200. Therefore, the differential pair of transistor devices can be fabricated approximately identically or proportionally with respect to the DUT(s) of each of the circuit dies 202, such that fabrication tolerances and temperature effects can affect the two semiconductor devices in approximately the same manner. As an example, the transistor devices of the DUT circuits 204 can be most closely fabrication matched to the DUTs of the circuit dies 202 that are most proximal to the DUT circuits 204 to provide a closest fabrication process match.

As described herein, the testing equipment 102 can be configured to implement a separate BTI testing process 106 on each of the DUT circuits 204. To correctly model the parametric shifts of the DUTs in the circuit dies 202, the testing equipment 102 can provide different parameters of the BTI stress provided in each of the separate BTI testing processes 106. Therefore, the parametric shifts of the DUTs in the circuit dies 202 can be modeled for different operating conditions and in different environments.

As an example, the testing equipment 102 can provide a BTI stress to one of the transistor devices of the differential transistor pair by providing a predefined voltage to a control input (e.g., gate) of the transistor device while grounding all other terminals of the transistor device (e.g., including a substrate body connection) at a predefined temperature. The combination of the predefined voltage and the predefined temperature can be different for each BTI testing process 106. As an example, the DUT circuits 204 can each be fabricated for the specific purpose of providing a singular BTI test process 106.

Given that the BTI stress of one of the transistor devices in each of the DUT circuits 204 effectively renders the transistor device as permanently operationally adjusted (e.g., as age simulated), the DUT circuits 204 can be discarded after the BTI testing process 106 (e.g., after singulation of the circuit dies 202). However, by including a quantity of DUT circuits 204 that can accommodate each combination of predefined voltage and predefined temperature for each BTI stress of a transistor device in one of the DUT circuits 204, the BTI test processes 106 can collectively model the parametric shifts of the DUTs in the circuit dies 202 at any of a variety of operating conditions and environments. As another example, the semiconductor wafer 200 can include a quantity of DUT circuits 204 that can facilitate multiple instances of each combination of voltage and temperature for BTI stresses in the BTI testing process 106 for each of respective multiple sets of DUT circuits 204. Therefore, the multiple instances of each combination of voltage and temperature can be applicable to DUTs on respective circuit dies 202 that are regionally proximal to each of the multiple sets of the DUT circuits 204 to accommodate fabrication process matching of proximal DUTs with respect to the DUT circuits 204.

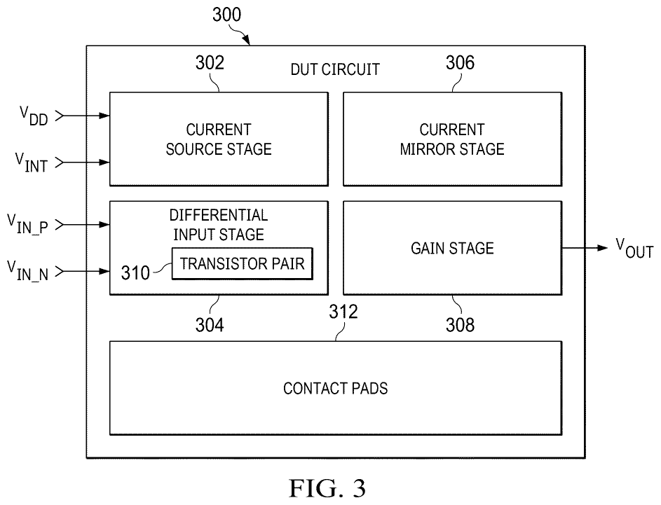

FIG. 3 is an example block diagram of a DUT circuit 300. The DUT circuit 300 can correspond to one of the DUT circuit(s) 112 or one of the DUT circuits 204. Therefore, reference is to be made to the examples of FIGS. 1 and 2 in the following description of the example of FIG. 3.

The DUT circuit 300 can be configured as an operational amplifier (OP-AMP) that includes a current source stage 302, a differential input stage 304, a current mirror stage 306, and a gain stage 308. The current source stage 302 is configured to provide at least one current in response to a source voltage V_{DD} and a bias voltage V_{INT}. The differential input stage 304 includes the differential transistor pair 310 (“TRANSISTOR PAIR”) that are each configured to conduct a portion of one of the current(s) provided from the current source stage 302 in response to a differential input voltage, demonstrated as a first input voltage V_{IN_P} and a second input voltage V_{IN_N}. As described above, the differential transistor pair 310 are fabrication matched (e.g., approximately identical) to each other, and fabrication matched to the DUTs of the circuit dies 202.

The current mirror stage 306 is configured to conduct the portions of the one current provided from differential input stage 304 at an approximately equal bias input at respective control terminals (e.g., gates) of current mirror transistors. The gain stage 308 is configured to provide the output voltage V_{OUT} based on a current provided from the current source stage 302 (e.g., a different current than the current provided through the differential input stage 304). The gain stage 308 can include a transistor device that can set the gain of the DUT circuit 300 (e.g., based on gate size characteristics) and which is controlled by the differential input stage 304. Therefore, the output voltage V_{OUT} can have an amplitude that is based on a difference in amplitude between the first input voltage V_{IN_P} and the second input voltage V_{IN_N}. In this manner, based on the gain of the DUT circuit 300 and based on the arrangement of the differential transistor pair 310, a difference in threshold voltage between the differential transistor pair 310 resulting from a BTI stress of one of the transistor devices of the differential transistor pair 310 can be measured with very high precision (e.g., in the microvolt range).

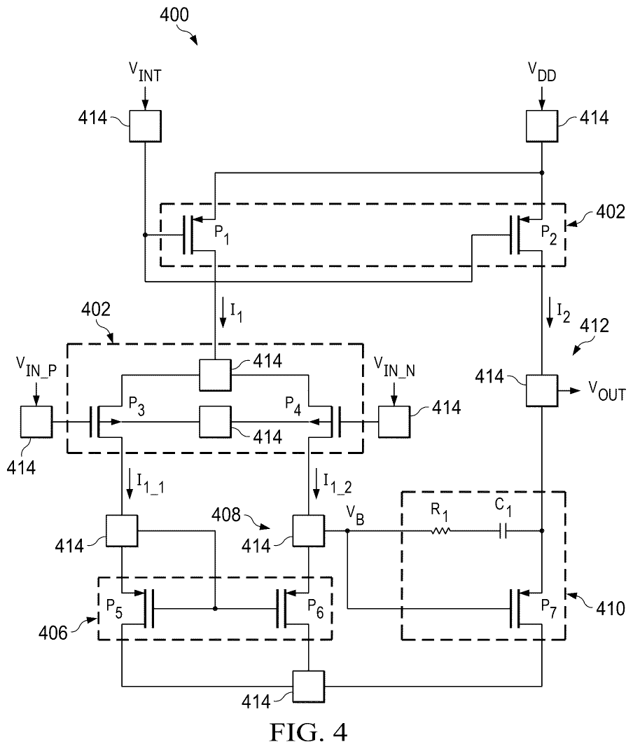

FIG. 4 is an example diagram of a DUT circuit 400. The DUT circuit 400 is demonstrated in the example of FIG. 4 as an OP-AMP. The DUT circuit 400 includes a plurality of transistor devices (hereinafter “transistors”) that are demonstrated as PMOS transistors. However, other arrangements or types of transistors can be implemented instead. The DUT circuit 400 can correspond to one of the DUT circuit(s) 112, one of the DUT circuits 204, and/or the DUT circuit 300. Therefore, reference is to be made to the examples of FIGS. 1-3 in the following description of the example of FIG. 4.

The DUT circuit 400 includes a current source stage 402 that includes a first source transistor P₁ and a second source transistor P₂. The first source transistor P₁ is configured to conduct a first current I₁ and the second source transistor P₂ is configured to conduct a second I₂ based on the source voltage V_{DD} and the bias voltage V_{INT}. As an example, the source transistors P₁ and P₂ can be fabrication matched (e.g., approximately identical) with respect to each other, such that the first and second currents I₁ and I₂ have equal amplitude.

The DUT circuit also includes a differential input stage 404 that includes a first input transistor P₃ and a second input transistor P₄. As described above, the input transistors P₃ and P₄ can be fabrication matched to each other (e.g., approximately identical), as well as to the DUTs of the circuit dies 202. The first input transistor P₃ is controlled by the input voltage V_{IN_P} and has a source coupled to the first source transistor P₁, and the second transistor P₄ is controlled by the input voltage V_{IN_N} and has a source that is also coupled to the first source transistor P₁. Therefore, each of input transistors P₃ and P₄ is configured to conduct a portion of the first current, demonstrated as I_{1_1} and I_{1_2}, respectively.

The DUT circuit 400 also includes a current mirror stage 406 that includes a first mirror transistor P₅ and a second mirror transistor P₆. As an example, the mirror transistors P₅ and P₆ can be fabrication matched (e.g., approximately identical) with respect to each other. In the example of FIG. 4, the first mirror transistor P₅ is gate-source coupled to act as a diode-connected transistor that conducts the first portion current I_{1_1}. The second mirror transistor P₆ has a gate coupled to the gate-source coupling of the first mirror transistor P₅ and has a drain coupled to a drain of the first mirror transistor P₅. Therefore, the second mirror transistor P₆ is mirrored to the first mirror transistor P₅ by having a same control bias to conduct the second portion current I_{1_2}. Additionally, the DUT circuit 400 includes a bias terminal 408 arranged between the source of the second mirror transistor P₆ and the drain (e.g., output) of the second input transistor P₄.

The DUT circuit 400 also includes a gain stage 410 that includes a gain transistor P₇, as well as a resistor R₁ and a capacitor C₁ arranged in series between the gate and the source of the gain transistor P₇. The gate of the gain transistor P₇ is coupled to the bias terminal 408, the drain of the gain transistor P₇ is coupled to the drains of the mirror transistors P₅ and P₆, and the source of the gain transistor P₇ is coupled to an output terminal 412 that is also coupled to the drain of the second source transistor P₂. Therefore, the gain transistor P₇ is configured to provide the output voltage V_{OUT} from the output terminal 412 based on the second current I₂ provided from the second source transistor P₂, and based on a bias voltage V_{B} at the bias terminal 408 responsive to the second portion current I_{1_2}. As an example, the gain transistor P₇ can have a size (e.g., gate size) that, along with the amplitudes of the source and/or bias voltages V_{DD} and/or V_{INT}, can set the gain of the DUT circuit 400. The bias voltage V_{B} can have an amplitude that is based on a difference in amplitude between the first input voltage V_{IN_P} and the second input voltage V_{IN_N}. Therefore, the output voltage V_{OUT} can have an amplitude that is based on the gain of the DUT circuit and the and the bias voltage V_{B}.

In the example of FIG. 4, the DUT circuit 400 further includes a plurality of contact pads 414 at each terminal between transistor devices and inputs/output. Particularly, the DUT circuit 400 includes a first contact pad 414 at an input terminal that provides the source voltage V_{DD} and a second contact pad 414 at an input terminal that provides the bias voltage V_{INT}. The DUT circuit 400 includes a third contact pad 414 at an input terminal that provides the first input voltage V_{IN_P} and a fourth contact pad 414 at an input terminal that provides the second input voltage V_{IN_N}. The DUT circuit 400 includes a fifth contact pad 414 at a terminal between the sources of the input transistors P₃ and P₄ and the drain of the first source transistor P₁. The DUT circuit 400 includes a sixth contact pad 414 at a terminal between the body connections of the input transistors P₃ and P₄. The DUT circuit 400 includes a seventh contact pad 414 at a terminal between the source of the first input transistor P₃ and the first mirror transistor P₅, and an eight contact pad 414 at a terminal coupled to the drains of the mirror transistors P₅ and P₆ and the gain transistor P₇. The DUT circuit 400 includes a ninth contact pad 414 at the bias terminal 408, and a tenth contact pad 414 at the output terminal 412.

To conduct a BTI testing process, the testing equipment 102 can couple to each of the contact pads 414, and can initially provide the differential voltage V_{IN_P} and V_{IN_N} and measure the output voltage V_{OUT}. As an example, the testing equipment 102 can provide a continuously variable amplitude (e.g., sweep from a low amplitude to a high amplitude) of one of the first and second input voltages V_{IN_P} and V_{IN_N} relative to a fixed amplitude of the other of the first and second input voltages V_{IN_P} and V_{IN_N}, and can measure the resultant continuously changing output voltage V_{OUT}. The testing equipment 102 can thus obtain a baseline measurement of the output voltage V_{OUT} in this manner.

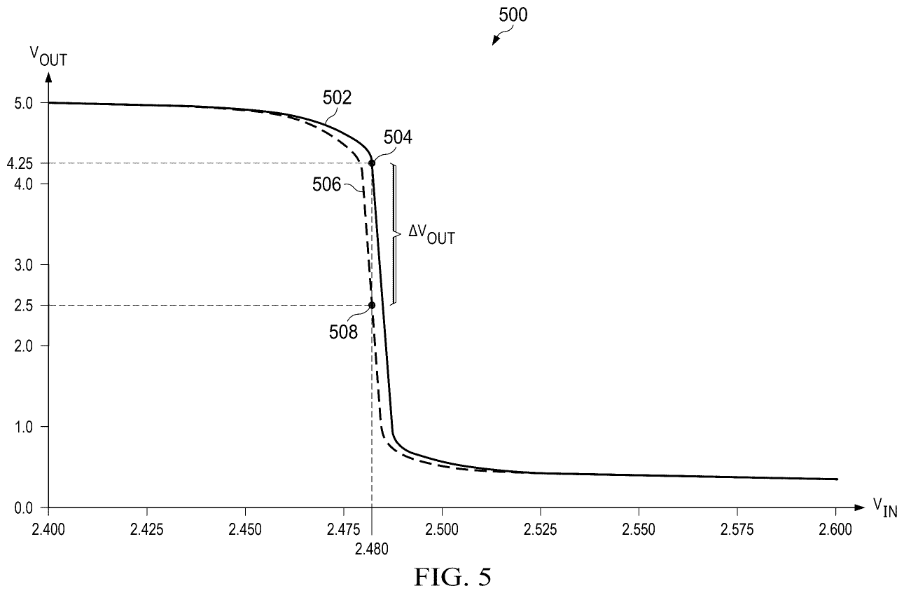

FIG. 5 is an example of a voltage graph 500. The voltage graph 500 plots a variable input voltage V_{IN} on the X-axis to a variable output voltage V_{OUT} on the Y-axis. The input voltage V_{IN} can correspond to the one of the input voltages V_{IN_P} and V_{IN_N} that is swept in a continuously variable amplitude from low amplitude to high amplitude. The graph 500 demonstrates a baseline curve of the output voltage V_{OUT} as a solid line 502. The variable amplitude of the output voltage V_{OUT} can be recorded by the testing equipment 102 and saved in the memory 116. The testing equipment 102 can determine the region of the greatest amplitude change of the output voltage V_{OUT}, and can thus determine the gain of the DUT circuit 400 based on the slope of the output voltage V_{OUT} in the approximately linear region of the greatest amplitude change. Alternatively, the gain can be modeled/estimated prior to fabrication of the DUT circuit 400.

The testing equipment 102 can then select an amplitude of the input voltage V_{IN} that is at a lower amplitude of the range of amplitudes of the input voltage V_{IN} that corresponds to the greatest change in amplitude of the output voltage V_{OUT}. The selected amplitude point is demonstrated at 504 in the baseline curve 502 of the output voltage V_{OUT}. The selected amplitude point 504 can thus correspond to an initial measurement of the output voltage V_{OUT}, prior to applying a BTI stress. In the example of FIG. 5, the selected amplitude point 504 is at an input voltage V_{IN} of approximately 2.480V, and the initial measurement of the output voltage V_{OUT} is approximately 4.25V.

Referring back to the example of FIG. 4, after obtaining the baseline measurement of the output voltage V_{OUT} at the selected amplitude of the input voltage V_{IN}, the testing equipment provides a BTI stress to one of the input transistors P₃ and P₄ (e.g., the one of the input transistors P₃ and P₄ in which the amplitude of the input voltage V_{IN} is swept). To provide the BTI stress, the testing equipment 102 can provide a predefined amplitude of the input voltage to the gate of the respective one of the input transistors P₃ and P₄ for a predefined duration of time at a predefined temperature.

In an example, the relevant transistor device is described below as the first transistor device P₃. The testing equipment 102 can be electrically connected to each of the ten contact pads 414. To provide the BTI stress, the testing equipment 102 can provide a zero voltage amplitude (e.g., ground connection) to each of the nine contact pads 414 that are not coupled to the gate of the first transistor device P₃. The testing equipment 102 can then provide the predefined amplitude of the first input voltage V_{IN_P} to the gate of the first transistor device P₃ for the predefined duration of time at the predefined temperature. Upon completion of the predefined duration of time, the BTI stress is complete to simulate the aging of the first input transistor P₃ to determine the estimated parametric shifts of the DUTs in the circuit dies 202.

The predefined duration of time can be any duration of time that is deemed sufficient for proper simulation of aging of the respective transistor device, and can be based on a standard, an estimate, and/or determined experimentally. The predefined amplitude of the first input voltage V_{IN_P} can be one of a plurality of static amplitudes that can be used to fully model the parametric shifted age-behavior of the DUTs of the circuit dies 202. For example, the predefined static amplitudes can be 7 volts, 8 volts, and 9 volts. The predefined temperature can be one of a plurality of temperatures that can be used to fully model the parametric shifted age-behavior of the DUTs of the circuit dies 202. For example, the predefined temperatures can be 125° C. and 175° C.

The testing equipment 102, in applying the BTI stress to the first input transistor P₃, can provide one combination of the predefined amplitude and predefined temperature. In the provided example, the BTI stress of the first transistor P₃ can be any of 7V at 125° C., 7V at 175° C., 8V at 125° C., 8V at 175° C., 9V at 125° C., and 9V at 175° C. To fully model the parametric shifted age-behavior of the DUTs of the circuit dies 202, the testing equipment 102 can provide one of the above combinations of predefined amplitude and predefined temperature to the first transistor device P₃ of the DUT circuit 400, and can provide each of the other combinations of predefined amplitude and predefined temperature to a first transistor device to a respective other one of the DUT circuits 204 on the semiconductor wafer 200 in separate respective BTI test processes 106 of DUT circuits 204. Therefore, the total of all combinations of the predefined amplitude and predefined temperature in separate BTI test processes 106 can result in sufficient data for accurate and complete modeling of the parametric shifted age-effects of the DUTs of the circuit dies 202.

Subsequent to providing the BTI stress to the first transistor device P₃, the testing equipment can again measure the output voltage V_{OUT}. With reference again to the example of FIG. 5, the graph 500 demonstrates a BTI stressed curve of the output voltage V_{OUT} as a dashed line 506. The variable amplitude of the BTI stressed output voltage V_{OUT} can be recorded by the testing equipment 102 and saved in the memory 116, although it may not be necessary for purposes of the BTI test process 106. The testing equipment 102 can then select the same amplitude of the input voltage V_{IN} (e.g., V_{IN_P} in the above example) that was selected in the baseline measurement of the amplitude of the output voltage V_{OUT}. The selected amplitude point is demonstrated at 508 in the BTI stressed curve 506 of the output voltage V_{OUT}. The selected amplitude point 508 is demonstrated as the same amplitude of the input voltage V_{IN} as the selected amplitude point 504 in the baseline measurement, demonstrated as an input voltage V_{IN} amplitude of approximately 2.480V. However, because the BTI stress changes the threshold voltage V_{T} of the respective transistor device (e.g., the first input transistor P₃), the same measurement point in the BTI stressed curve 506 results in a lesser amplitude of the measured output voltage V_{OUT}. In the example of FIG. 5, the selected amplitude point 508 of approximately 2.480V results in a BTI stressed measurement of the output voltage V_{OUT} at approximately 2.5V. The example of FIG. 5 demonstrates the difference between the amplitudes of the output voltage V_{OUT} in the initial measurement and the BTI stressed measurement as ΔV_{OUT} (e.g., approximately 1.75V).

The testing equipment 102 can thus calculate the change in threshold voltage ΔV_{T} of the first input transistor P₃, and thus the difference in threshold voltages of the input transistors P₃ and P₄. The change in threshold voltage ΔV_{T} can be calculated as follows:

$$Δ {V}_{T} = Δ {V}_{OUT} / G \qquad Equation 1$$

Where: G is the gain of the DUT circuit 400 (e.g., as calculated based on the slope of the output voltage V_{OUT} in the region of greatest amplitude change).

Equation 1 can thus provide the calculated change in threshold voltage ΔV_{T} with very high precision (e.g., in the microvolt range) based on the high gain of the DUT circuit 400 in determining the difference in output voltage V_{OUT}. Accordingly, the determination of the calculated change in threshold voltage ΔV_{T} can result in a much higher precision than conventional BTI test processes that can model only to within a millivolt range. With the calculated change in threshold voltage ΔV_{T} for each combination of predefined voltage and predefined temperature of the BTI stresses of the respective separate BTI test processes 106, the testing equipment 102 can thus fully and accurately model the parametric shifted age-effects of the DUTs on the semiconductor wafer 200.

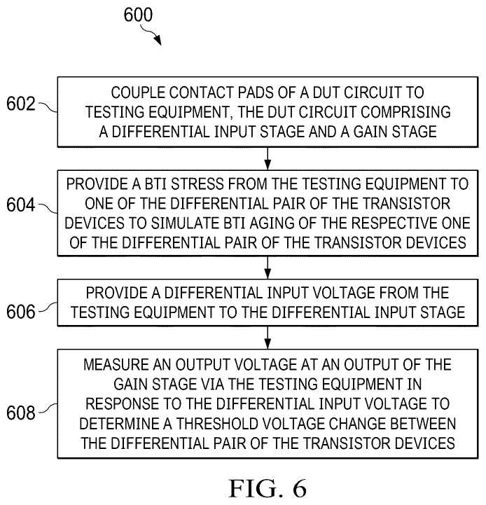

In view of the foregoing structural and functional features described above, methodologies in various aspects of the description will be better appreciated with reference to FIG. 6. The method of FIG. 6 is not limited by the illustrated order, as some aspects could, in the present description, occur in different orders and/or concurrently with other aspects from that shown and described herein. Moreover, not all illustrated features may be required to implement methodologies in an aspect of the present examples.

FIG. 6 is an example of a method 600 for performing a BTI test process (e.g., a BTI test process 106) for a plurality of DUTs (e.g., the DUTs 110). At 602, contact pads (e.g., the contact pads 312) of a DUT circuit (e.g., the DUT circuit(s) 112) are coupled to testing equipment (e.g., the testing equipment 102). The DUT circuit can include a differential input stage (e.g., the differential input stage 304) and a gain stage (e.g., the gain stage 308). The differential input stage can include a differential pair of transistor devices (e.g., the differential transistor pair 310) that are fabrication matched to the DUTs. At 604, a BTI stress is provided from the testing equipment to one of the differential pair of the transistor devices to simulate BTI aging of the respective one of the differential pair of the transistor devices. At 606, a differential input voltage (e.g., the input voltages V_{IN_P} and V_{IN_N}) is provided from the testing equipment to the differential input stage. At 608, an output voltage (e.g., the output voltage V_{OUT}) is measured at an output (e.g., the output terminal 412) of the gain stage via the testing equipment in response to the differential input voltage to determine a threshold voltage change (e.g., the change in threshold voltage ΔV_{T}) between the differential pair of the transistor devices.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

In this description, the term “couple” can cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, a device that is “configured to” perform a task or function can be configured (e.g., programmed and/or hardwired) at a time of manufacturing by a manufacturer to perform the function and/or can be configurable (or reconfigurable) by a user after manufacturing to perform the function and/or other additional or alternative functions. The configuring can be through firmware and/or software programming of the device, through a construction and/or layout of hardware components and interconnections of the device, or a combination thereof. Furthermore, a circuit or device that is described herein as including certain components can instead be configured to couple to those components to form the described circuitry or device. For example, a structure described herein as including one or more semiconductor elements (such as transistors), one or more passive elements (such as resistors, capacitors, and/or inductors), and/or one or more sources (such as voltage and/or current sources) can instead include only the semiconductor elements within a single physical device (e.g., a semiconductor die and/or integrated circuit (IC) package) and can be configured to couple to at least some of the passive elements and/or the sources to form the described structure, either at a time of manufacture or after a time of manufacture, such as by an end-user and/or a third-party.

The phrase “based on” means “based at least in part on”. Therefore, if X is based on Y, X can be a function of Y and any number of other factors.

Modifications are possible in the described embodiments, and other embodiments are possible, within the scope of the claims.

What is claimed is:

1. A method for performing a bias temperature instability (BTI) test process for a plurality of devices-under-test (DUTs), the method comprising:
coupling contact pads of a DUT circuit to testing equipment, the DUT circuit comprising a differential input stage and a gain stage, the differential input stage comprising a differential pair of transistor devices that are fabrication matched to the DUTs;
providing a BTI stress from the testing equipment to one of the differential pair of transistor devices to simulate BTI aging of the respective one of the differential pair of transistor devices;
providing a differential input voltage from the testing equipment to the differential input stage; and
measuring an output voltage at an output of the gain stage via the testing equipment in response to the differential input voltage to determine a threshold voltage change between the differential pair of transistor devices.

2. The method of claim 1, wherein measuring the output voltage comprises:
measuring the output voltage at a first time prior to providing the BTI stress to the respective one of the differential pair of transistor devices;
measuring the output voltage at a second time subsequent to providing the BTI stress to the respective one of the differential pair of transistor devices; and
determining the threshold voltage change based on a difference in amplitude of the output voltage between the first time and the second time.

3. The method of claim 2, wherein measuring the output voltage further comprises dividing the difference in amplitude of the output voltage between the first time and the second time by a gain of the gain stage to determine the threshold voltage change between the differential pair of transistor devices.

4. The method of claim 3, further comprising determining the gain of the gain stage based on a slope of the output voltage across a range of amplitudes of the differential input voltage.

5. The method of claim 1, wherein providing the differential input voltage comprises:
providing a first input voltage to a first one of the differential pair of transistor devices at a fixed amplitude; and
providing a second input voltage to a second one of the differential pair of transistor devices, the second input voltage being continuously variable from a first amplitude to a second amplitude,
wherein measuring the threshold voltage change comprises continuously measuring the output voltage at the gain stage in response to the fixed amplitude of the first input voltage provided concurrently with the continuously variable amplitude of the second input voltage.

6. The method of claim 5, wherein measuring the output voltage comprises selecting:
an amplitude of the second input voltage along the continuously variable amplitude corresponding to an output measurement amplitude;
measuring a first amplitude of the output voltage in response to the output measurement amplitude of the second input voltage at a first time prior to providing the BTI stress to the respective one of the differential pair of transistor devices; and
measuring a second amplitude of the output voltage in response to the output measurement amplitude of the second input voltage at a second time subsequent to providing the BTI stress to the respective one of the differential pair of transistor devices.

7. The method of claim 6, wherein measuring the output voltage comprises measuring a slope of the output voltage across the continuously variable amplitude of the second input voltage to determine a gain of the gain stage.

8. The method of claim 7, wherein measuring the output voltage further comprises dividing the difference in the amplitude of the output voltage between the first time and the second time by the gain of the gain stage to determine the threshold voltage change between the differential pair of transistor devices.

9. The method of claim 1, wherein providing the BTI stress comprises:
providing a predefined voltage to a control input terminal of the respective one of the differential pair of transistor devices at a predefined temperature for a predefined duration of time; and
providing a ground connection to each remaining terminal of the respective one of the differential pair of transistor devices at the predefined temperature for the predefined duration of time.

10. The method of claim 9, wherein the DUT circuit is one of a plurality of DUT circuits, wherein providing the BTI stress comprises providing each of a different combination of one of a plurality of predefined voltages to the control input terminal of the respective one of the differential pair of transistor devices and one of a plurality of predefined temperatures for the predefined duration of time for each of the plurality of DUT circuits.

11. A semiconductor device comprising:
a current source stage having a first input, a second input, and a first output and a second output, the first input of the current source stage being adapted to receive a bias voltage, and the second input of the current source stage being adapted to receive a bias control voltage;
a differential input stage comprising a first input transistor device and a second input transistor device, the first input transistor device having a control input, an input, an output, and a terminal, the second input transistor device having a control input, an input, an output, and a terminal, the control input of the first input transistor device being adapted to receive a first control input voltage, the control input of the second input transistor device being adapted to receive a second control input voltage, the input of each of the first and second input transistor devices being coupled to the first output of the current source stage, and the terminal of the first input transistor device being coupled to the terminal of the second input transistor device;
a current mirror stage having a first input, a second input, and an output, the first input of the current mirror stage being coupled to the output of the first input transistor device, and the second input of the current mirror stage being coupled to the output of the second input transistor device;
a gain stage having a first input, a second input, and an output, the first input of the gain stage being coupled to the output of the second input transistor device, the second input of the gain stage being coupled to the second output of the current source stage, and the output of the gain stage being coupled to the output of the current mirror stage;
a first contact pad coupled to the control input of the first input transistor device;
a second contact pad coupled to the control input of the second input transistor device;
a third contact pad coupled to the second input of each of the first and second input transistor devices;
a fourth contact pad coupled to the output of the first input transistor device;
a fifth contact pad coupled to the output of the second input transistor device;
a sixth contact pad coupled to the terminal of the first and second input transistor devices; and
a seventh contact pad coupled to the second input of the gain stage.

12. The semiconductor device of claim 11, further comprising:
an eighth contact pad coupled to the first input of the current source stage;
a ninth contact pad coupled to the second input of the current source stage; and
a tenth contact pad coupled to the output of the current mirror stage.

13. The semiconductor device of claim 11, wherein the current source stage comprises:
a first source transistor device having a control input, an input, and an output, the control input of the first source transistor device being adapted to receive the bias control voltage, the input of the first source transistor device being adapted to receive the bias voltage, the output of the first source transistor device being coupled to the input of the first input transistor device; and
a second source transistor device having a control input, an input, and an output, the control input of the second source transistor device being adapted to receive the bias control voltage, the input of the second source transistor device being adapted to receive the bias voltage, the output of the second source transistor device being coupled to the input of the second input transistor device.

14. The semiconductor device of claim 11, wherein the current mirror stage comprises:
a first mirror transistor device having a control input, an input, and an output, the control input and the input of the first mirror transistor device being coupled to the output of the first input transistor device, the output of the first mirror transistor device being coupled to the output of the gain stage; and
a second mirror transistor device having a control input, an input, and an output, the control input of the second mirror transistor device being coupled to the output of the first input transistor device, the input of the second mirror transistor device being coupled to the output of the second input transistor device, the output of the second mirror transistor device being coupled to the output of the gain stage.

15. The semiconductor device of claim 11, wherein the gain stage comprises a gain transistor device having a control input, an input, and an output, the control input of the gain transistor device being coupled to the output of the second input transistor device, the input of the gain transistor device being coupled to the second output of the current source stage, and the output of the gain transistor device being coupled to the output of the current mirror stage.

16. The semiconductor device of claim 11, wherein the semiconductor device is an operational amplifier (OP-AMP).

17. A test system for performing a bias temperature instability (BTI) test process of a plurality of devices-under-test (DUTs), the system comprising:
a semiconductor wafer comprising:
the plurality of circuit dies, each of the circuit dies comprising at least one DUT; and
at least one DUT circuit each comprising a differential input stage and a gain stage, the differential input stage comprising a differential pair of transistor devices that are fabrication matched to the DUTs; and
testing equipment to which contact pads of each of the at least one DUT circuit are arranged to be coupled, the testing equipment being configured to provide BTI stress to one of the differential pair of transistor devices to simulate BTI aging of the respective one of the differential pair of transistor devices, to provide a differential input voltage to the differential pair of transistor devices, and to measure an output voltage at an output of the gain stage in response to the differential input voltage to determine a threshold voltage change between the differential pair of transistor devices.

18. The system of claim 17, wherein the at least one DUT circuit further comprises:
a current source stage configured to provide a first current and a second current, wherein the differential pair of transistor devices are each configured to conduct a portion of the first current in response to receiving the respective differential input voltage; and
a current mirror stage coupled to the differential input stage, the current mirror stage comprising a bias terminal through which the portion of the first current is provided, wherein the gain stage is coupled to the bias terminal and is configured to provide the output voltage in response to the differential input voltage.

19. The system of claim 17, wherein the testing equipment is configured to:
measure the output voltage at a first time prior to providing the BTI stress to the respective one of the differential pair of transistor devices;
measure the output voltage at a second time subsequent to providing the BTI stress to the respective one of the differential pair of transistor devices; and
determine the threshold voltage change based on a difference in amplitude of the output voltage between the first time and the second time.

20. The system of claim 19, wherein the testing equipment is further configured to:
provide a first input voltage to a first one of the differential pair of transistor devices at a fixed amplitude;
provide a second input voltage to a second one of the differential pair of transistor devices, the second input voltage being continuously variable from a first amplitude to a second amplitude; and
measure a threshold voltage of the second one of the differential pair of transistor devices by continuously measuring the output voltage at the gain stage in response to the fixed amplitude of the first input voltage provided concurrently with the continuously variable amplitude of the second input voltage.

21. The system of claim 19, wherein the testing equipment is configured to:
determine a gain of the gain stage by measuring a slope of the output voltage across the continuously variable amplitude of the second input voltage; and
divide the difference in amplitude of the output voltage between the first time and the second time by the gain to determine the threshold voltage change between the differential pair of transistor devices.

22. A semiconductor wafer comprising:
a plurality of circuit dies, each of the circuit dies comprising at least one device-under-test (DUT);
a plurality of DUT circuits, each of the DUT circuits comprising:
a current source stage configured to provide a first current and a second current;
a differential input stage comprising a differential pair of transistor devices that are each configured to conduct a portion of the first current in response to receiving a respective differential input voltage, each of the differential pair of transistor devices being fabrication matched to the at least one DUT of each of the circuit dies;
a current mirror stage coupled to the differential input stage, the current mirror stage comprising a bias terminal through which the portion of the first current is provided;
a gain stage coupled to the bias terminal and being configured to provide an output voltage based on the second current in response to the differential input voltage; and
contact pads configured to provide a bias temperature instability (BTI) stress to one of the differential pair of transistor devices to perform a BTI test of the at least one DUT of each of the circuit dies via the respective one of the DUT circuits.

23. The wafer of claim 22, wherein the current source stage comprises:
a first source transistor device configured to conduct the first current in response to a bias control voltage; and
a second source transistor device configured to conduct the second current in response to the bias control voltage.

24. The wafer of claim 22, wherein the current mirror stage comprises:
a first mirror transistor device coupled to a first one of the differential pair of transistor devices, the first mirror transistor device being diode-connected to conduct a first portion of the first current; and
a second mirror transistor device coupled to a second one of the differential pair of transistor devices, the second mirror transistor device having a control input terminal coupled to a control input terminal of the first mirror transistor device to conduct a second portion of the first current, wherein the bias terminal is arranged between the second one of the differential pair of transistor devices and the second mirror transistor device.

25. The wafer of claim 22, wherein the gain stage comprises a gain transistor device that is configured to conduct the second current in response to a control voltage provided at the bias terminal.
